(19) United States
(12) Patent Application Publication
(10) Pub. No.: US 2026/0129910 A1
(43) Pub. Date: May 7, 2026

(54) SEMICONDUCTOR DEVICE

(71) Applicants: Samsung Electronics Co., Ltd., Suwon-si (KR); POSTECH RESEARCH AND BUSINESS DEVELOPMENT FOUNDATION, Pohang-si (KR)

(72) Inventors: Bonwon KOO, Suwon-si (KR); Yong Young NOH, Pohang-si (KR); Young Jae KANG, Suwon-si (KR); Kiyeon YANG, Suwon-si (KR); Jaeyun LEE, Pohang-si (KR); Minwoo CHOI, Suwon-si (KR)

(73) Assignees: Samsung Electronics Co., Ltd., Suwon-si (KR); POSTECH RESEARCH AND BUSINESS DEVELOPMENT FOUNDATION, Pohang-si (KR)

(21) Appl. No.: 19/280,981

(22) Filed: Jul. 25, 2025

(30) Foreign Application Priority Data
Nov. 7, 2024 (KR) 10-2024-0157439

(51) Int. Cl. H10D 30/67

(52) U.S. Cl. CPC H10D 30/6737; H10D 30/6756

(57) ABSTRACT

A semiconductor device may include a substrate, source/drain electrodes on the substrate, a channel layer on the source/drain electrodes, a barrier film on the channel layer, a gate electrode on the barrier film, and an intermediate layer between a corresponding one of the source/drain electrodes and the channel layer, the intermediate layer including metal oxide, wherein the channel layer may include an oxide semiconductor material, and the oxide semiconductor material may include tellurium (Te) oxide and one or more oxides of sulfur (S) or selenium (Se).

### CROSS-REFERENCE TO RELATED APPLICATION

This application claims priority to Korean Patent Application No. 10-2024-0157439 filed on Nov. 7, 2024 and all the benefits accruing therefrom under 35 U.S.C. § 119, the contents of which are incorporated by reference in its entirety.

### BACKGROUND

The present disclosure relates to semiconductor devices.

Oxide semiconductor materials generally have a larger band gap than silicon-based semiconductors. Oxide semiconductor materials with a larger band gap have low leakage current and relatively good electrical performance. In general, as p-type oxide semiconductors, materials including copper (Cu), tin (Sn), or nickel (Ni) has been known, but their hole field effect mobility is insufficient, which limits the development of devices including PN junction diodes (e.g., complementary metal-oxide-semiconductors (CMOS)).

In a field effect transistor (FET) having a channel layer including a p-type oxide semiconductor, the channel layer and source/drain electrodes have a relatively large difference in work function, which increases the contact resistance (R_{cnt}), and thus there is a problem in that holes do not smoothly move.

### SUMMARY

Some example embodiment of the present disclosure provide semiconductor devices that reduce or prevent the problem of increased contact resistance due to a difference in work function between a channel layer and source/drain electrodes.

Effects of the present disclosure are not limited to those mentioned above, and other effects not mentioned will be clearly understood by those of ordinary skill in the art from the following description.

According to an example embodiment of the present disclosure, a semiconductor device includes a substrate, source/drain electrodes on the substrate, a channel layer on the source/drain electrodes, a barrier film on the channel layer, a gate electrode on the barrier film, and an intermediate layer between a corresponding one of the source/drain electrodes and the channel layer, the an intermediate layer including metal oxide, wherein the channel layer includes an oxide semiconductor material, and the oxide semiconductor material includes tellurium (Te) oxide and one or more oxides of sulfur (S) or selenium (Se).

According to an example embodiment of the present disclosure, a semiconductor device includes a substrate, an insulating layer on the substrate, source/drain electrodes on the substrate, a channel layer on the source/drain electrodes, a barrier film on the channel layer, a gate electrode on the barrier film, and an intermediate layer between a corresponding one of the source/drain electrodes and the channel layer, the intermediate layer including a metal oxide, wherein the channel layer includes an oxide semiconductor material that includes one or more of sulfur (S), selenium (Se) or tellurium (Te) and has an oxygen-deficient composition.

According to an example embodiment of the present disclosure, a semiconductor device includes a substrate, an insulating layer on the substrate, source/drain electrodes on the insulating layer, a channel layer on the source/drain electrodes, a barrier film on the channel layer, a gate electrode on the barrier film, and an intermediate layer between a corresponding one of the source/drain electrodes and the channel layer, the intermediate layer surrounding at least a portion of the source/drain electrodes, the intermediate layer including metal oxide having an oxygen-deficient composition, wherein the channel layer includes a p-type oxide semiconductor material that includes one or more of sulfur (S), selenium (Se) or tellurium (Te), and has an oxygen-deficient composition and an amorphous structure, and a work function of the intermediate layer is smaller than a work function of the channel layer and greater than a work function of the gate electrode.

### BRIEF DESCRIPTION OF THE DRAWINGS

The drawings shown in the present disclosure are according to some example embodiments, and ratios of the width, height or thickness of each component is for describing the present disclosure in detail, and the ratio may be different from the actual ones. In addition, each component illustrated in the drawings may be exaggerated to describe the present disclosure in detail. In addition, in a coordinate system shown in the drawing, each axis may be perpendicular to the others, a direction pointed by an arrow may be a + direction, and a direction opposite to the direction pointed by the arrow (a direction rotated by 180 degrees) may be a − direction, in which:

FIG. 1 is a plan view showing at least a portion of a semiconductor device according to an example embodiment of the present disclosure; and

FIG. 2 is an enlarged view of area A in FIG. 1.

### DETAILED DESCRIPTION OF EMBODIMENTS

Unless specifically limited in the present specification, the units of properties may follow the International System of Units (SI).

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

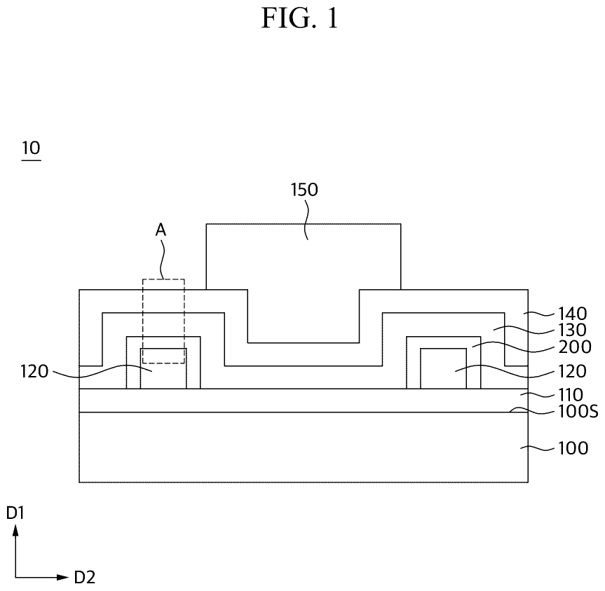

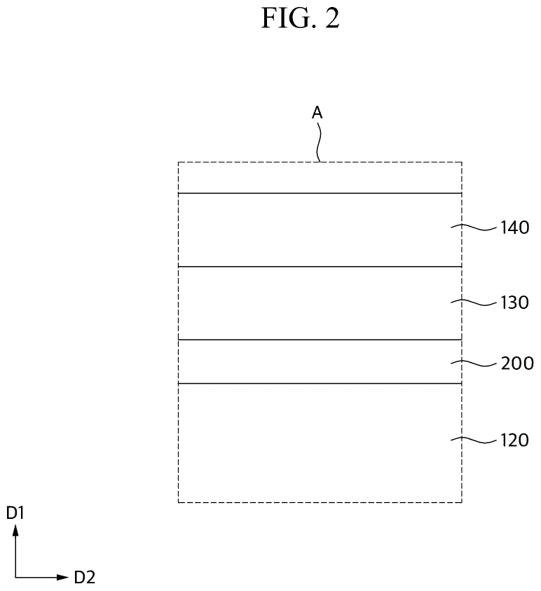

FIG. 1 is a plan view showing at least a portion of a semiconductor device 10 according to an example embodiment of the present disclosure. FIG. 2 is an enlarged view of area A of FIG. 1.

In an example embodiment of the present specification, a first direction D1 may refer to a direction perpendicular to a surface 100S of a substrate 100. The second direction D2 may intersect the first direction D1. In one example, the second direction D2 may refer to a direction parallel to the surface 100S of the substrate 100.

In one example, a semiconductor device 10 may include a substrate 100, source/drain electrodes 120, a channel layer 130, a barrier film 140, a gate electrode 150, and an intermediate layer 200.

In one example, the semiconductor device 10 may be applied to the semiconductor field, the display field, or the solar cell field. In one example, the semiconductor device 10 may be one selected from the group consisting of a system large scale integration (LSI), flash memory, dynamic random-access memory (DRAM), state RAM (SRAM), electrically erasable programmable read-only-memory (EEPROM), phase-change RAM (PRAM), magnetoresistive RAM (MRAM), ferroelectric RAM (FeRAM), and resistive RAM (RRAM). In one example, the semiconductor device 10 may include a plurality of individual devices of various types. The plurality of individual devices may not be particularly limited as the devices are those used in the art, and may, for example, include a metal-oxide-semiconductor field effect transistor (MOSFET), such as a complementary metal-oxide semiconductor (CMOS) transistor or the like or an image sensor, such as a CMOS imaging sensor (CIS) or the like, an active device, a passive device, or the like. In one example, the semiconductor device 10 may include a thin film transistor (TFT), and the structure of the thin film transistor in one example may refer to FIG. 1.

In one example, the substrate 100 may be a silicon semiconductor substrate, a plastic substrate, a glass substrate, a compound semiconductor substrate, a ceramic substrate, or a silicon-on-insulator (SOI) substrate, but is not limited thereto. In one example, the substrate 100 may include, although not illustrated separately, an impurity region by doping, a peripheral circuit for selecting and controlling a memory cell, or the like.

In one example, the semiconductor device 10 may include an insulating film 110 disposed on the substrate 100. The insulating film 110 may include an insulating material. In the present specification, the insulating material may include one or more selected from the group consisting of silicon oxide, silicon nitride, silicon oxynitride, low-k materials, and high-k materials, but is not limited thereto. In the present specification, the low-k material may have a permittivity less than 3.9, and may include, for example, one or more selected from the group consisting of fluorinated tetraethylorthosilicate (FTEOS), hydrogen silsesquioxane (HSQ), Bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, and mesoporous silica, but is not limited thereto. In the present specification, the high-k material may have a permittivity of 3.9 or higher, and may include, for example, one or more selected from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but is not limited thereto.

In one example, the source/drain electrodes 120 may be disposed on the substrate 100. The source/drain electrodes 120 may be disposed on the insulating film 110. There may be a plurality of source/drain electrodes 120, and each source/drain electrode 120 may be spaced apart from the other. Some of the plurality of source/drain electrodes 120 may be source electrodes and others may be drain electrodes.

In one example, the source/drain electrodes 120 may include impurities. Impurities may vary depending on the type of conductivity. For example, n-type source/drain electrodes 120 may include an n-type dopant, which is an impurity including at least one of phosphorus (P), arsenic (As), antimony (Sb), or bismuth (Bi). In addition, for example, p-type source/drain electrodes 120 may include a p-type dopant, which is an impurity including at least one of boron (B) or gallium (Ga). At least some of the plurality of source/drain electrodes 120 may be of an n-type or p-type. Some of the plurality of source/drain electrodes 120 may be of an n-type and the others may be of a p-type.

In one example, the source/drain electrodes 120 may include one or more selected from the group consisting of silicon, silicon doped with impurities, metal, metal nitride, metal silicide, and metal oxide. In the present specification, the metal may include one or more selected from the group consisting of gold (Au), silver (Ag), platinum (Pt), calcium (Ca), ytterbium (Yb), aluminum (Al), copper (Cu), titanium (Ti), tantalum (Ta), rubidium (Ru), tungsten (W), molybdenum (Mo), nickel (Ni), tin (Sn), palladium (Pd), lead (Pb), and cobalt (Co). In the present specification, the metal nitride may include one or more selected from the group consisting of titanium nitride (TiN), titanium aluminum nitride (TiAlN), tantalum silicon nitride (TaSiN), and rubidium titanium nitride (RuTiN). In the present specification, the metal silicide may include one or more selected from the group consisting of titanium silicide (TiSi), tantalum silicide (TaSi), nickel silicide (NiSi), and cobalt silicide (CoSi). In the present specification, the metal oxide may include one or more selected from the group consisting of gold oxide (AuOₓ), platinum oxide (PtOₓ), silver oxide (AgOₓ), palladium oxide (PdOₓ), iridium oxide (IrOₓ), and rubidium oxide (RuOₓ).

In one example, the barrier film 140 may be disposed on the source/drain electrodes 120. The barrier film 140 may be disposed on the channel layer 130. In one example, the barrier film 140 may include one or more selected from the group consisting of metal oxide, silicon oxide, silicon nitride, silicon oxynitride, a low-k material, and a high-k material, but is not limited thereto. In one example, the metal oxide may include one or more selected from the group consisting of, for example, aluminum oxide (AlO) and tin oxide (SnO).

In one example, the gate electrode 150 may be disposed on the barrier film 140. The gate electrode 150 may be at least partially in non-contact with the source/drain electrodes 120. In one example, the gate electrode 150 may be electrically connected to a word line. In one example, the gate electrode 150 may include the aforementioned conductive material. In the present specification, the conductive material may include one or more selected from the group consisting of doped polysilicon, metal, metal nitride, metal silicide, and metal oxide.

In one example, the channel layer 130 may be disposed on the source/drain electrodes 120.

In one example, the channel layer 130 may include an oxide semiconductor material. The channel layer 130 may include one or more of sulfur (S) or selenium (Se), and may include tellurium (Te).

In one example, the oxide semiconductor material may include tellurium (Te) oxide. The oxide semiconductor material may include one or more oxides of sulfur (S) or selenium (Se). The oxide semiconductor material may include tellurium (Te) oxide and may further include one or more oxides of sulfur (S) or selenium (Se).

In one example, the oxide semiconductor material may be of a p type.

In one example, the oxide semiconductor material may be amorphous. Thereby, an on/off ratio of the semiconductor device 10 may be improved.

In one example, the oxide semiconductor material may have an oxygen deficient composition. In the present specification, oxygen deficiency may refer to a mismatch state in which a match ratio of an element combined with oxygen and oxygen in an oxide is not satisfied. For example, the mismatch state may refer to a state in which the octet rule or the 18-electron rule is not satisfied. For example, when a mismatch ratio of an element A combined with oxygen and oxygen O in an oxide is A:O=1:2, the oxide with an oxygen-deficient composition may satisfy AO₂₋ₓ(0<x<2).

In one example, the channel layer 130 may include an oxide semiconductor material represented by the following Chemical formula 1.

TeₐQ_{b}Oₓ [Chemical formula 1]

In Chemical formula 1, Q is one or more of sulfur (S) or selenium (Se), and 0<a≤1, 0<b≤1, and 0<x≤4 may be satisfied.

In Chemical formula 1, 0<a≤1, 0<b≤1, and 0<x<4 may be satisfied.

In Chemical formula 1, 0.8≤a/b≤1.2, 0.9≤a/b≤1.1, or 0.95≤a/b≤1.05 may be satisfied.

As described above, the oxide semiconductor material may include one or more of sulfur (S) or selenium (Se) and include tellurium (Te), and ratios a, b, and x between the elements and oxygen may be appropriately adjusted, thereby improving the hole field effect mobility and/or improving the on/off ratio of the semiconductor device 10.

In one example, the oxide semiconductor material may include the Q in Chemical formula 1 in an amount of about 0.5 at % to about 5 at %, about 1 at % to about 4.5 at %, or about 1.5 at % to about 4 at % relative to the total number of atoms of tellurium (Te), the Q, and the oxygen O. Thereby, the hole field effect mobility may be improved and/or the on/off ratio of the semiconductor device 10 may be improved.

In one example, moles of the oxygen O per one mole of tellurium (Te) in the oxide semiconductor material may be about 0.8 to about 1.7, about 1 to about 1.5, or about 1.1 to about 1.4. The oxide semiconductor material having a ratio of tellurium (Te) and oxygen (O) satisfying the above-described range may improve hole field effect mobility and/or improve the on/off ratio of the semiconductor device 10.

In one example, the tellurium (Te) included in the oxide semiconductor material may include ionized tellurium (Te) and non-ionized tellurium (Te). The ionized tellurium (Te) may include, for example, one or more of Te⁴⁺ or Te²⁺. The non-ionized tellurium (Te) may be represented as Te⁰. Thereby, a shallow acceptor state formed by the 5p orbital of tellurium (Te) may be used as a hole conduction channel.

In one example, the oxide semiconductor material may include selenium (Se), and the selenium (Se) may include ionized selenium. The ionized selenium (Se) may include, for example, Se²⁺. Therefore, the ionized selenium (Se) may passivate an oxygen-deficient portion, allowing a partially empty 4P state to be used as the hole conduction channel.

In one example, a thickness of the channel layer 130 may be about 2 nm or more and about 100 nm or less, about 3 nm or more and about 50 nm or less, about 4 nm or more and about 20 nm or less, or about 5 nm or more and about 15 nm or less, but is not particularly limited thereto. Thereby, the hole field effect mobility may be improved. The thickness of the channel layer 130 may refer to the length in the first direction D1, for example, with reference to FIG. 2.

In one example, the channel layer 130 may have a work function of about 4 eV or more and about 8 eV or less, about 4.5 eV or more and about 7.5 eV or less, about 5 eV or more and about 7 eV or less, or about 6 eV or more and about 6.95 eV or less. Thereby, the hole field effect mobility may be improved and/or the on/off ratio of the semiconductor device 10 may be improved.

In one example, the channel layer 130 may be formed by deposition, and the deposition may be performed through chemical vapor deposition (CVD), physical vapor deposition (PVD), atomic layer deposition (ALD), or the like.

For example, the channel layer 130 may be formed by thermal evaporation or sputtering. In one example, one or more of thermal evaporation or sputtering may be performed at a temperature of the substrate 100 of about 15° C. to about 35° C., for example, at room temperature. In one example, one or more of the thermal evaporation or sputtering may be performed under a vacuum pressure of less than about 10⁻³ Torr to reduce or minimize impurities.

In one example, when forming the channel layer 130 through thermal evaporation, a thermal evaporation speed may be controlled to about 1 Å/s to about 100 Å/s in order to reduce or prevent a surface roughness of the channel layer 130 from increasing while reducing or minimizing a process time.

In one example, when forming the channel layer 130 through sputtering, a molar ratio of tellurium (Te) and oxygen (O) in the channel layer 130 may be controlled by adjusting a partial pressure of oxygen (O₂) and argon (Ar) plasma. Then, the channel layer 130 formed through sputtering may be annealed in an air or oxygen atmosphere, depending on the case, and the annealing may be performed at a temperature of about 100° C. to about 300° C. Then, the annealing may be performed at a temperature ranging from room temperature to about 300° C. in air.

In one example, the intermediate layer 200 may be disposed between the source/drain electrodes 120 and the channel layer 130. The intermediate layer 200 may include metal oxide.

In one example, a work function of the intermediate layer 200 may be smaller than the work function of the channel layer 130 and greater than a work function of the gate electrode 150. Thereby, the problem of increased contact resistance (R_{cnt}) due to the difference in work function between the channel layer 130 and the source/drain electrodes 120 may be reduced or prevented.

In one example, a ratio (W_{I}/W_{C}) of a work function W_{I} of the intermediate layer 200 to a work function W_{C} of the channel layer 130 may be about 0.5 or more and less than about 1, about 0.6 or more and about 0.95 or less, about 0.7 or more and about 0.9 or less, or about 0.8 or more and 0.88 or less. In one example, the ratio (W_{I}/W_{G}) of the work function W_{I} of the intermediate layer 200 to the work function W_{G} of the gate electrode 150 may be more than about 1 and about 2 or less, about 1.1 or more and about 1.8 or less, about 1.2 or more and about 1.6 or less, or about 1.3 or more and about 1.5 or less. Thereby, the problem of increased contact resistance (R_{cnt}) due to the difference in work function between the channel layer 130 and the source/drain electrodes 120 may be reduced or prevented.

In one example, the intermediate layer 200 may have the work function of about 3 eV or more and about 7 eV or less, about 3.5 eV or more and about 6.8 eV or less, about 4 eV or more and about 6.7 eV or less, about 4.5 eV or more and about 6.6 eV or less, about 5 eV or more and about 6.4 eV or less, or about 5.5 eV or more and about 6.2 eV or less. Thereby, the problem of increased contact resistance (R_{cnt}) due to the difference in work function between the channel layer 130 and the source/drain electrodes 120 may be reduced or prevented.

In one example, the metal oxide may have an oxygen deficient composition. The metal oxide may include one or more selected from the group consisting of tungsten oxide (WOx), molybdenum oxide (MoOx), indium oxide (InOx), tin oxide (SnOx), and gallium oxide (GaOx), but is not limited thereto. In the above-mentioned materials, x may be a number that does not satisfy a mismatch ratio of oxygen and the combined metal element.

In one example, the thickness of the intermediate layer 200 may be about 0.1 nm or more and about 10 nm or less, about 0.2 nm or more and about 9 nm or less, about 0.3 nm or more and about 8 nm or less, about 0.4 nm or more and about 7 nm or less, about 0.5 nm or more and about 6 nm or less, about 0.6 nm or more and about 5 nm or less, about 0.7 nm or more and about 4 nm or less, about 0.8 nm or more and about 3 nm or less, about 0.9 nm or more and about 2 nm or less, or about 0.95 nm or more and about 1.5 nm or less. Thereby, the hole field effect mobility may be improved and/or the on/off ratio of the semiconductor device 10 may be improved. The thickness of the intermediate layer 200 may refer to the length in the first direction D1, for example, with reference to FIG. 2.

In one example, a ratio (T1/T2) of a thickness T1 of the intermediate layer 200 to a thickness T2 of the channel layer 130 is about 0.001 or more and about 10 or less, about 0.01 or more and about 9 or less, about 0.05 or more and about 8 or less, about 0.1 or more and about 7 or less, about 0.3 or more and about 6 or less, about 0.5 or more and about 5 or less, about 0.6 or more and about 4 or less, about 0.7 or more and about 3 or less, about 0.8 or more and about 2 or less, or about 0.9 or more and about 1 or less, or 0.9.

In one example, the thickness T1 of the intermediate layer 200 may be smaller than the thickness T2 of the channel layer 130. In this case, for example, the ratio (T1/T2) of the thickness T1 of the intermediate layer 200 to the thickness T2 of the channel layer 130 may be about 0.001 or more to less than about 1, about 0.005 or more to less than about 1, about 0.01 or more to less than about 1, about 0.02 or more to less than about 1, about 0.03 or more to less than about 1, about 0.04 or more to less than about 1, about 0.05 or more to less than about 1, about 0.06 or more to less than about 1, about 0.07 or more to less than about 1, about 0.08 or more to less than about 1, about 0.09 or more to less than about 1, or about 0.1 or more to less than about 1.

In one example, the intermediate layer 200 may surround at least a portion of the source/drain electrodes 120. The intermediate layer 200 may be at least partially in contact with the source/drain electrodes 120. The channel layer 130 may not be in contact with the source/drain electrodes 120 due to the presence of the intermediate layer 200. In one example, the source/drain electrodes 120 may be at least partially in contact with the insulating layer 110. The intermediate layer 200 may be in contact with the source/drain electrodes 120 in at least some of regions that are not in contact with the insulating layer 110.

The present disclosure can provide a semiconductor device that secures good hole mobility characteristics and/or a high on/off ratio and/or reduces or minimizes leakage current.

Effects of the present disclosure are not limited to those mentioned above, and other effects not mentioned will be clearly understood by those skilled in the art from the description below.

In the above, some example embodiments of the present disclosure have been described with reference to the accompanying drawings, but example embodiments of the present disclosure are not limited to the above example embodiments and may be manufactured in various different forms and those of ordinary skill in the art to which the present disclosure pertains may understand that the additional or alternative example embodiments may be embodied in other specific forms without departing from the technical spirit or essential features of the present disclosure. Therefore, it is to be appreciated that the example embodiments described above are intended to be illustrative in all respects and not restrictive.

What is claimed is:

1. A semiconductor device comprising:
a substrate;
source/drain electrodes on the substrate;
a channel layer on the source/drain electrodes;
a barrier film on the channel layer;
a gate electrode on the barrier film; and
an intermediate layer between a corresponding one of the source/drain electrodes and the channel layer, the intermediate layer including metal oxide,
wherein the channel layer includes an oxide semiconductor material, and
the oxide semiconductor material includes tellurium (Te) oxide and one or more oxides of sulfur (S) or selenium (Se).

2. The semiconductor device of claim 1, wherein a work function of the intermediate layer is smaller than a work function of the channel layer and greater than a work function of the gate electrode.

3. The semiconductor device of claim 1, wherein a ratio (W_{I}/W_{C}) of a work function (W_{I}) of the intermediate layer to a work function (W_{C}) of the channel layer is 0.5 or more and less than 1.

4. The semiconductor device of claim 1, wherein a ratio (W_{I}/W_{G}) of a work function (W_{I}) of the intermediate layer to a work function (W_{G}) of the gate electrode is more than 1 and 2 or less.

5. The semiconductor device of claim 1, wherein the metal oxide has an oxygen deficient composition.

6. The semiconductor device of claim 5, wherein the metal oxide includes one or more selected from the group consisting of WOx, MoOx, InOx, SnOx, and GaOx.

7. The semiconductor device of claim 1, wherein a ratio (T1/T2) of a thickness (T1) of the intermediate layer to a thickness (T2) of the channel layer is 0.001 or more and 10 or less.

8. The semiconductor device of claim 1, wherein a thickness of the intermediate layer of 0.1 nm or more and 10 nm or less.

9. The semiconductor device of claim 1, wherein a thickness (T1) of the intermediate layer is smaller than a thickness (T2) of the channel layer.

10. The semiconductor device of claim 1, wherein the intermediate layer surrounds at least a portion of the source/drain electrodes.

11. The semiconductor device of claim 1, wherein the oxide semiconductor material is of a p-type.

12. The semiconductor device of claim 1, wherein the oxide semiconductor material is amorphous.

13. The semiconductor device of claim 1, wherein the oxide semiconductor material has an oxygen-deficient composition.

14. The semiconductor device of claim 13, wherein moles of oxygen (O) per one mole of tellurium (Te) in the oxide semiconductor material are 0.8 to 1.7.

15. The semiconductor device of claim 1, wherein the oxide semiconductor material is represented by the following Chemical formula 1:
TeₐQ_{b}Oₓ [Chemical Formula 1]
in Chemical formula 1, Q is one or more of sulfur (S) or selenium (Se), and 0<a≤1, 0<b≤1, and 0<x≤4.

16. The semiconductor device of claim 15, wherein the oxide semiconductor material includes Q in an amount of 0.5 at % to 5 at % relative to a total number of atoms of tellurium (Te), Q, and oxygen (O).

17. The semiconductor device of claim 1, wherein tellurium (Te) included in the oxide semiconductor material includes ionized tellurium and non-ionized tellurium.

18. The semiconductor device of claim 1, wherein
the oxide semiconductor material includes selenium (Se), and
the selenium (Se) includes ionized selenium.

19. A semiconductor device comprising:
a substrate;
an insulating layer on the substrate;
source/drain electrodes on the substrate;
a channel layer on the source/drain electrodes;
a barrier film on the channel layer;
a gate electrode on the barrier film; and
an intermediate layer between a corresponding one of the source/drain electrodes and the channel layer, the intermediate layer including metal oxide,
wherein the channel layer includes an oxide semiconductor material that includes one or more of sulfur (S), selenium (Se) or tellurium (Te) and has an oxygen-deficient composition.

20. A semiconductor device comprising:
a substrate;
an insulating layer on the substrate;
source/drain electrodes on the insulating layer;
a channel layer on the source/drain electrodes;
a barrier film on the channel layer;
a gate electrode on the barrier film; and
an intermediate layer between a corresponding one of the source/drain electrodes and the channel layer, the intermediate layer surrounding at least a portion of the source/drain electrodes, the intermediate layer including metal oxide having an oxygen-deficient composition,
wherein the channel layer includes a p-type oxide semiconductor material that includes one or more of sulfur (S), selenium (Se) or tellurium (Te), and has an oxygen-deficient composition and an amorphous structure, and
a work function of the intermediate layer is smaller than a work function of the channel layer and greater than a work function of the gate electrode.
